(19) United States
(12) Patent Application Publication
(10) Pub. No.: US 2013/0168721 A1
(43) Pub. Date: Jul. 4, 2013

(54) LIGHT EMITTING DEVICE

(71) Applicants: Atsuhiro Hori, Kagoshima (JP); Yuji Takase, Kagoshima (JP)

(72) Inventors: Atsuhiro Hori, Kagoshima (JP); Yuji Takase, Kagoshima (JP)

(73) Assignee: PANASONIC CORPORATION, Osaka (JP)

(21) Appl. No.: 13/813,842

(22) PCT Filed: Aug. 3, 2011
(86) PCT No.: PCT/JP2011/004398

§ 371 Date: Mar. 11, 2013

(30) Foreign Application Priority Data
Aug. 24, 2010 (JP) 2010-186816

(51) Int. Cl. H01L 33/40

(52) U.S. Cl. CPC H01L 33/405
USPC 257/98

(57) ABSTRACT

A light emitting device includes a light transmissive substrate, a semiconductor layer formed on the substrate, and having an n-type layer, a light emitting layer, and a p-type layer, a reflective electrode formed on the semiconductor layer, and reflecting light from the light emitting layer toward the substrate, a barrier electrode formed on the reflective electrode, and a cover electrode formed on the barrier electrode. The reflective electrode includes a Ag layer, the cover electrode includes an layer, and the barrier electrode reduces interdiffusion between Ag and Al.

### BACKGROUND

The present disclosure relates to light emitting devices, and in particular, light emitting devices having a reflective electrode and a cover electrode.

Light emitted from an active layer in a flip chip light emitting device travels not only in a direction of a light transmissive substrate, but also in a direction opposite to the substrate. In order to improve light extraction efficiency, the flip chip light emitting device is provided with a reflective electrode which reflects the light having been emitted toward the direction opposite to the substrate. For example, a p electrode is formed to have a multilayer structure formed by stacking an ohmic electrode made of nickel (Ni) etc. in ohmic contact with a p type contact layer, and a reflective electrode made of aluminum (Al) etc. having a high optical reflectance.

If a reflective electrode made of Al is directly stacked on an ohmic electrode made of Ni, interdiffusion of atoms between the Ni layer and the Al layer may be caused, and the characteristics of the ohmic electrode may be deteriorated, and the operating voltage may increase. Therefore, it has been considered to form a barrier electrode, made of a high melting point metal, such as molybdenum (Mo) etc., between the ohmic electrode and the reflective electrode (see Japanese Patent Publication No. 2002-26392). The formation of the barrier electrode is expected to be able to reduce interdiffusion of metal atoms between the ohmic electrode and the reflective electrode, and prevent the operating voltage from increasing.

It has also been considered to allow the p electrode to have a multilayer structure of, e.g., a nickel (Ni) layer and a silver (Ag) layer, and the ohmic electrode to serve as a reflective electrode. Such a structure in which part of the ohmic electrode is made of the Ag layer having a high optical reflectance is expected to improve the reflectance of the ohmic electrode, and light extraction efficiency from the substrate.

### SUMMARY

However, the conventional light emitting device which improves the reflectance of the ohmic electrode has the following problems. On the ohmic electrode, a cover electrode including an Al layer is formed for bonding etc. The present inventors have found that, when a cover electrode is formed, if a light emitting device is energized for a long time, or the light emitting device is subjected to a high temperature, brightness of the light emitting device decreases. They also have found that, along with the decrease of the brightness, a drive voltage increases. It is required to maintain stable brightness in the light emitting device. In particular, when the light emitting device is used as an illumination apparatus etc., it is necessary to the light emitting device for a long time, and changes with time in the brightness would be a serious problem. If the light emitting device is mounted on a printed-wiring substrate etc., it is subjected to a high temperature in a reflow furnace, and therefore, the decrease of the brightness due to the high temperature would also be a serious problem.

It is an object of the present disclosure to solve the above problems, and to provide a light emitting device which prevents or reduces a decrease in brightness and an increase in a drive voltage due to, for example, operation for a long time, and application of heat.

In order to attain the above object, an example light emitting device includes, between a reflective electrode and a cover electrode, a barrier electrode which reduces interdiffusion between the cover electrode and the reflective electrode.

Specifically, an example light emitting device includes: a light transmissive substrate; a semiconductor layer formed on the substrate, and having an n-type layer, a light emitting layer, and a p-type layer; a reflective electrode formed on the semiconductor layer, and reflecting light from the light emitting layer toward the substrate; a barrier electrode formed on the reflective electrode; and a cover electrode formed on the barrier electrode, wherein the reflective electrode includes a Ag layer, the cover electrode includes an Al layer, and the barrier electrode reduces interdiffusion between Ag and Al.

According to the light emitting device of the present disclosure, it is possible to prevent or reduce a decrease in brightness and an increase in a drive voltage due to, for example, operation for a long time, and application of heat.

### BRIEF DESCRIPTION OF THE DRAWINGS

FIG. 1 is a cross-sectional view showing a light emitting device according to an embodiment.

FIG. 2 is a graph showing reflection characteristics of the light emitting device according to the embodiment.

FIG. 3 is a cross-sectional view showing a light emitting device according to a variation.

### DETAILED DESCRIPTION

An example light emitting device includes: a light transmissive substrate; a semiconductor layer formed on the substrate, and having an n-type layer, a light emitting layer, and a p-type layer; a reflective electrode formed on the semiconductor layer, and reflecting light from the light emitting layer toward the substrate; a barrier electrode formed on the reflective electrode; and a cover electrode formed on the barrier electrode, wherein the reflective electrode includes a Ag layer, the cover electrode includes an Al layer, and the barrier electrode reduces interdiffusion between Ag and Al.

The present inventors have found that brightness decreases and a drive voltage increases because the Al is diffused by operation for a long time and application of heat, and reaches the Ag layer to change characteristics of the Ag layer. In the example light emitting device, the barrier electrode is provided between the reflective electrode and the cover electrode, and the diffusion of the Al layer can be reduced. This makes it possible to prevent the reflectance of the Ag layer from being reduced due to the modification of the Ag layer, prevent brightness from decreasing, and prevent a drive voltage from increasing.

In the example light emitting device, a size of the barrier electrode may be equal to or larger than that of the Ag layer, and a size of the Al layer may be equal to or larger than that of the barrier electrode. Since the size of the barrier electrode is equal to or larger than that of the Ag layer, it is possible to prevent diffusion of Al to the Ag layer. Since the size of the Al layer is equal to or larger than that of the barrier electrode, light having passed through the vicinity of the reflective electrode can be reflected by the Al layer. Therefore, a reflection effect can be improved.

In the example light emitting device, the barrier electrode may be a metal layer having a single layer structure or a metal layer having a multilayer structure formed by stacking multiple metal layers, and the metal layer may be a layer including any one of titanium (Ti), nickel (Ni), rhodium (Rh), tantalum (Ta), or tungsten (W) or an alloy layer including two or more of titanium (Ti), nickel (Ni), rhodium (Rh), tantalum (Ta), or tungsten (W).

In this case, the metal layer may have a thickness of 100 nm or more. Since the metal layer may have a thickness of 100 nm or more, it is possible to efficiently reduce diffusion of the Al from the Al layer to the Ag layer.

In the example light emitting device, the reflective electrode may include a Ni layer having the same planar shape as the Ag layer, the barrier electrode may be made of titanium, and the size of the barrier electrode may be larger than that of the reflective electrode, and smaller than that of the Al layer.

If the barrier electrode is made of the Ti layer having a size smaller than the Al layer, and larger than the reflective electrode made of the Ni layer and the Ag layer which have the same outline shape, the Ni layer, the Ag layer, and the Ti layer can be formed by different mask patterns.

In the example light emitting device, the reflective electrode may include a platinum (Pt) layer having the same planar shape as the Ag layer, the barrier electrode may be made of titanium, and the size of the barrier electrode may be equal to that of the reflective electrode.

With such a structure, the Pt layer, the Ag layer, and the Ti layer can be formed by the identical mask pattern. Therefore, it is possible to omit a step of removing the mask pattern after stacking the Pt layer and the Ag layer, and a step of forming another mask pattern for forming the Ti layer.

### Embodiment

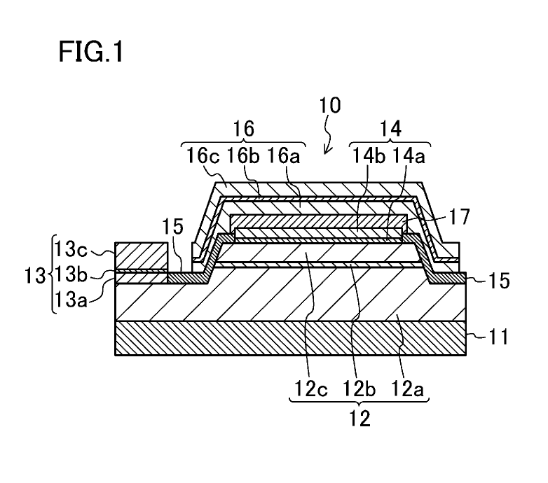

As shown in FIG. 1, a light emitting device 10 according to an embodiment is a flip chip light emitting diode (LED) including a light transmissive substrate 1, a semiconductor layer 12 stacked on the substrate 1, and an n electrode 13 and a p electrode 14 which are formed on the semiconductor layer 12 and supply power. In the description of the embodiment, the substrate 11 is a gallium nitride (GaN) substrate, and any substrates may be adopted as long as they allow light to transmit therethrough, and the semiconductor layer to grow thereon. For example, a sapphire substrate etc. can be used.

The semiconductor layer 12 includes an N—GaN layer 12a which is an n-type layer, a light emitting layer 12b, and a P—GaN layer 12c which is a p-type layer, the N—GaN layer 12a, the light emitting layer 12b, and the P—GaN layer 12c being sequentially stacked on the substrate 11. A buffer layer may be provided between the substrate 11 and the N—GaN layer 12a. An n-type dopant in the N—GaN layer 12a may be, for example, Si or Ge. The N—GaN layer 12a may have a thickness of approximately 2 μm.

The light emitting layer 12b includes at least Ga and N, and further includes a proper amount of In as necessary. By controlling the amount of the In, a desired emission wavelength can be obtained. The light emitting layer 12b may have a single layer structure, or may have, e.g., a multiple quantum well structure in which one or more pairs each including an InGaN layer and a GaN layer are alternately stacked. The multiple quantum well structure of the light emitting layer 12b can further improve brightness.

The P—GaN layer 12c is stacked directly on the light emitting layer 12b or on the light emitting layer 12b with a semiconductor layer, including at least Ga and N, interposed between the P—GaN layer 12c and the light emitting layer 12b. A p-type dopant in the P—GaN layer 12c may be Mg etc. The P—GaN layer 12c may have a thickness of approximately 0.1 μm.

On the semiconductor layer 12, the n electrode 13 and the p electrode 14 are formed. The n electrode 13 is provided in a region located on the N—GaN layer 12a, the region being formed by selectively etching and exposing part of the P—GaN layer 12c, the light emitting layer 12b, and the N—GaN layer 12a. The n electrode 13 includes an Al layer 13a, a Ti layer 13b, and a gold (Au) layer 13c sequentially formed on the semiconductor layer 12.

The p electrode 14 is stacked on the P—GaN layer 12c. The p electrode 14 includes a Ni layer 14a and a Ag layer 14b sequentially formed on the semiconductor layer 12. The p electrode 14 has the Ag layer 14b having a high reflectance, and serves as a reflective electrode.

The Ni layer 14a serves as an adhesive layer which improves adhesiveness between the P—GaN layer 12c and the Ag layer 14b. The Ni layer 14a may have a thickness of approximately 0.1 nm—approximately 5 nm.

A side surface of the P—GaN layer 12c, a side surface of the light emitting layer 12b, and a surface of N—GaN layer 12a which are exposed by etching and located in the vicinity of the p electrode 14 are covered with a silicon oxide (SiO₂) layer 15 serving as a protective layer.

On the p electrode 14, a barrier electrode 17 is formed. In the embodiment, the barrier electrode 17 is a Ti layer. The barrier electrode 17 which is a Ti layer has a thickness of approximately 100 nm. In the embodiment, the barrier electrode 17 is formed in a region larger than that of the p electrode 14. Therefore, the size of the barrier electrode 17 is larger than that of the p electrode 14. The barrier electrode 17 may be formed as shown below, for example. First, the SiO₂ layer 15 is formed on the semiconductor layer 12 which has been selectively etched, and then, the SiO₂ layer 15 is selectively removed to selectively expose the P—GaN layer 12c. Subsequently, by using a mask pattern, the p electrode 14 is formed on the P—GaN layer 12c which has been exposed. After the mask pattern for forming the p electrode 14 is removed, the Ti layer is formed, and the Ti layer is selectively removed so that unnecessary part of the Ti layer is removed. When the Ti layer is selectively removed, the Ti layer may be left in a region larger than that of the Ag layer 14b.

On the barrier electrode 17, a cover electrode 16 is formed. The cover electrode 16 includes an Al layer 16a, a Ti layer 16b, and an Au layer 16c. The Al layer 16a may have a thickness of approximately 250 nm. The Al layer 16a is formed in a region larger than that of the Ti layer which is the barrier electrode 17. Therefore, the Al layer 16a is formed in a region larger than that of the Ag layer 14b of the p electrode 14.

Light emitted from the light emitting layer 12b toward the p electrode 14 is reflected toward the substrate 11 in the Ag layer 14b. Since the Al layer 16a is formed in the region larger than that of the barrier electrode 17, light having leaked from the vicinity of the Ag layer 14b to reach the cover electrode 16 is also reflected toward the substrate 11 by the Al layer 16a. Therefore, the light emitting device 10 of the embodiment can provide high light extraction efficiency. The Ti layer 16b may have a thickness of approximately 100 nm. The Au layer 16c may have a thickness of approximately 1300 nm.

In the light emitting device 10 according to the embodiment, the Ti layer which is the barrier electrode 17 is formed on the p electrode 14, and is located between the Ag layer 14b which is the reflective electrode and the Al layer 16a which is the cover electrode 16. With such a configuration, the barrier electrode 17 can prevent Al of the Al layer 16a from being diffused and reaching the Ag layer 14b due to operation for a long time, and application of high heat. Therefore, this can prevent the reflectance of the Ag layer 14b from being reduced and a resistance value from increasing, and can prevent brightness of the light emitting device 10 from decreasing and the drive voltage of the light emitting device 10 from increasing. As a result, the light emitting device 10 having a high quality can be provided.

In the embodiment, the Ti layer is used for the barrier electrode 17, and instead of the Ti layer, the barrier electrode 17 may be, for example, a Rh layer, a Ni layer, a Ta layer or a W layer. Or the barrier electrode 17 may be a multilayer formed by stacking, for example, a Ti layer, Rh layer, a Ni layer, a Ta layer, and a W layer. Or the barrier electrode 17 may be a layer made of, for example, an alloy including any of, e.g., Ti, Rh, Ni, Ta, and W or a multilayer formed by stacking, e.g., Ti, Rh, Ni, Ta and W. In any cases, the barrier electrode 17 preferably has a thickness of 100 nm or more.

Multiple light emitting devices according to the embodiment are fabricated, and a measurement result of the reflectance of the light emitting devices will be shown below. A light emitting device A includes the barrier electrode 17 made of a Ti layer having a thickness of 100 nm, a light emitting device B includes the barrier electrode 17 made of a multilayer formed by stacking a Ni layer having a thickness of 100 nm and a Ti layer having a thickness of 100 nm, and a light emitting device C the barrier electrode 17 made of a Rh layer having a thickness of 100 nm. A light emitting device D does not include the barrier electrode 17, and light emitting devices E and F respectively include a Pt layer and a Cr layer each having a thickness of 30 nm instead of the barrier electrode 17.

Two light emitting devices A, two light emitting devices B, and two light emitting devices C were fabricated, and were heated at a temperature of 300° C. for about 3 minutes. The reflectance of each light emitting device before the heating was compared with the reflectance after the heating. The difference between the reflectance before the heating and the average reflectance after the heating is divided by the reflectance before the heating, and the obtained value is considered as a re he Ag layer 14b duction rate of the reflectance.

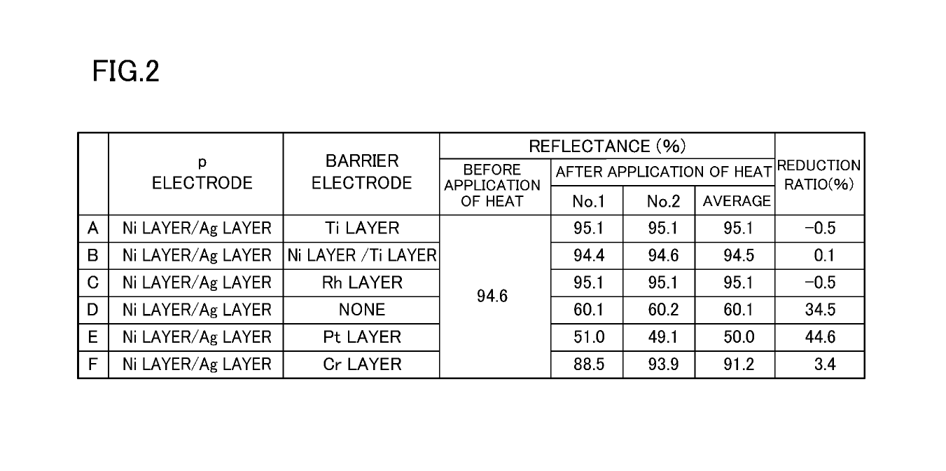

As shown in FIG. 2, in the light emitting devices A-C including the barrier electrode 17, the reduction rate of the reflectance is less than 1%. Values of the reflectance include errors of about 1%, and therefore, a negative value of the reduction rate in the light emitting devices A and B may be a measurement error. Accordingly, it is assumed that the reflectances of the light emitting devices A-C are hardly affected by the heating.

In contrast, in the light emitting device D not including the barrier electrode 17, the reduction rate of the reflectance is approximately 34.5%, and in the light emitting device E including the Pt layer instead of the barrier electrode 17, the reduction rate of the reflectance is approximately 44.6%. In the light emitting device F including the Cr layer instead of the barrier electrode 17, the reduction rate of the reflectance exceeds 1% though it is smaller than that of the light emitting devices D and E.

In view of the above result, it is clear that the formation of the barrier electrode made of Ti etc. can reduce the reduction of the reflectance of the Ag layer by the application of heating.

### Variation of Embodiment

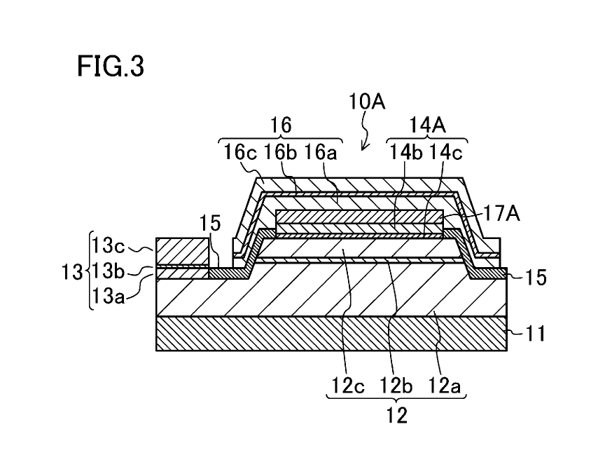

As shown in FIG. 3, a light emitting device 10A according to a variation including a p electrode 14A and a barrier electrode 17A which serve as reflective electrodes. In the embodiment, the p electrode has a multilayer structure formed by stacking the Ni layer and the Ag layer, and the p electrode 14A in the variation has a multilayer structure formed by stacking a Pt layer 14c and a Ag layer 14b. The barrier electrode 17A is a Ti layer, and has a planar shape and a size which are same as those of the p electrode 14A.

Since the p electrode 14A has the multilayer structure formed by stacking the Pt layer 14c and the Ag layer 14b, it is possible to form the Ti layer which is the barrier electrode 17A by using the identical mask pattern used for forming the p electrode 14A. Therefore, a step of removing the mask pattern for forming the p electrode 14A and a step of forming the mask pattern for forming the barrier electrode 17A can be omitted. Therefore, it is possible to simplify the fabrication steps while preventing diffusion of Al from the Al layer 16a to the Ag layer 14b.

In FIG. 3, the barrier electrode 17A has the same size as the Ag layer 14b, and an Al layer 16a of the cover electrode 16 is formed in a region larger than that of the barrier electrode 17A. However, the barrier electrode 17A may be formed in a region larger than that of the Ag layer 14b. The Al layer 16a of the cover electrode 16 may have the same size as the barrier electrode 17A.

The light emitting device of the present disclosure can reduce a decrease in brightness and an increase in a drive voltage due to, for example, operation for a long time, and application of heat, and in particular, the light emitting device has a reflective electrode and a cover electrode, and is useful as, e.g., a light emitting device extracting light from a substrate.
10 light emitting device
10A light emitting device
11 substrate
12 semiconductor layer
12a N—GaN layer
12b light emitting layer
12c P—GaN layer
13 n electrode
13a Al layer
13b Ti layer
13c Au layer
14 p electrode
14A p electrode
14a Ni layer
14b Ag layer
14c Pt layer
15 SiO₂ layer
16 cover electrode
16a Al layer
16b Ti layer
16c Au layer
17 barrier electrode
17A barrier electrode

1. A light emitting device, comprising:
a light transmissive substrate;
a semiconductor layer formed on the substrate, and having an n-type layer, a light emitting layer, and a p-type layer;
a reflective electrode formed on the semiconductor layer, and reflecting light from the light emitting layer toward the substrate;
a barrier electrode formed on the reflective electrode; and
a cover electrode formed on the barrier electrode, wherein
the reflective electrode includes a silver layer,
the cover electrode includes an aluminum layer, and
the barrier electrode reduces interdiffusion between silver and aluminum.

2. The light emitting device of claim 1, wherein
a size of the barrier electrode is equal to or larger than that of the silver layer, and
a size of the aluminum layer is equal to or larger than that of the barrier electrode.

3. The light emitting device of claim 1, wherein
the barrier electrode is a metal layer having a single layer structure or a metal layer having a multilayer structure formed by stacking multiple metal layers, and
the metal layer is a layer including any one of titanium, nickel, rhodium, tantalum, or tungsten or an alloy layer including two or more of titanium, nickel, rhodium, tantalum or tungsten.

4. The light emitting device of claim 3, wherein
the metal layer has a thickness of 100 nm or more.

5. The light emitting device of claim 4, wherein
the reflective electrode includes a nickel layer having a same planar shape as the silver layer,
the barrier electrode is made of titanium, and
the size of the barrier electrode is larger than that of the reflective electrode, and smaller than that of the aluminum layer.

6. The light emitting device of claim 4, wherein
the reflective electrode includes a platinum layer having a same planar shape as the silver layer,
the barrier electrode is made of titanium, and
the size of the barrier electrode is equal to that of the reflective electrode.

7. The light emitting device of claim 3, wherein
the reflective electrode includes a nickel layer having a same planar shape as the silver layer,
the barrier electrode is made of titanium, and
the size of the barrier electrode is larger than that of the reflective electrode, and smaller than that of the aluminum layer.

8. The light emitting device of claim 3, wherein
the reflective electrode includes a platinum layer having a same planar shape as the silver layer,
the barrier electrode is made of titanium, and
the size of the barrier electrode is equal to that of the reflective electrode.

9. The light emitting device of claim 2, wherein
the reflective electrode includes a nickel layer having a same planar shape as the silver layer,
the barrier electrode is made of titanium, and
the size of the barrier electrode is larger than that of the reflective electrode, and smaller than that of the aluminum layer.

10. The light emitting device of claim 2, wherein
the reflective electrode includes a platinum layer having a same planar shape as the silver layer,
the barrier electrode is made of titanium, and
the size of the barrier electrode is equal to that of the reflective electrode.

11. The light emitting device of claim 1, wherein
the reflective electrode includes a nickel layer having a same planar shape as the silver layer,
the barrier electrode is made of titanium, and
the size of the barrier electrode is larger than that of the reflective electrode, and smaller than that of the aluminum layer.

12. The light emitting device of claim 1, wherein
the reflective electrode includes a platinum layer having a same planar shape as the silver layer,
the barrier electrode is made of titanium, and
the size of the barrier electrode is equal to that of the reflective electrode.

13. The light emitting device of claim 1, wherein
the barrier electrode is a metal layer having a single layer structure or a metal layer having a multilayer structure formed by stacking multiple metal layers, and
the metal layer is a layer including any one of titanium, nickel, rhodium, tantalum, or tungsten or an alloy layer including two or more of titanium, nickel, rhodium, tantalum or tungsten.

14. The light emitting device of claim 13, wherein
the reflective electrode includes a nickel layer having a same planar shape as the silver layer,
the barrier electrode is made of titanium, and
the size of the barrier electrode is larger than that of the reflective electrode, and smaller than that of the aluminum layer.

15. The light emitting device of claim 13, wherein
the reflective electrode includes a platinum layer having a same planar shape as the silver layer,
the barrier electrode is made of titanium, and
the size of the barrier electrode is equal to that of the reflective electrode.
